(19) United States
(12) Patent Application Publication
(10) Pub. No.: US 2007/0104639 A1
(43) Pub. Date: May 10, 2007

(54) Method for manufacturing garnet single crystal and garnet single crystal manufactured thereby

(76) Inventor: Tae-Hyun Youn, Gyeonggi-Do (KR)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/582,213

(22) PCT Filed: Dec. 11, 2003
(86) PCT No.: PCT/KR03/02714

§ 371 Date: Jun. 8, 2006

(51) Int. Cl. C01G 49/00; C30B 11/00

(52) U.S. Cl. 423/594.1; 117/74

(57) ABSTRACT

Disclosed herein is a method for manufacturing a magnetic garnet single crystal from a melt containing an alkali metal oxide or carbide, garnet single crystal raw materials and Bi₂O₃—B₂O₃—PbO as a flux by liquid phase epitaxy (LPE) wherein the garnet single crystal is grown at a relative low temperature due to a reduced viscosity of the melt, and the grown garnet single crystal has a uniform thickness and a specular surface without any crystal defects. Further disclosed is a magnetic garnet single crystal manufactured by the method.

### TECHNICAL FIELD

The present invention relates to a method for manufacturing a magnetic garnet single crystal, and a magnetic garnet single crystal manufactured by the method. More particularly, the present invention relates to a method for manufacturing a magnetic garnet single crystal using a melt containing garnet single crystal raw materials and Bi₂O₃—B₂O₃—PbO as a flux by liquid phase epitaxy (LPE) wherein the garnet single crystal is grown at a relative low temperature due to a reduced viscosity of the melt, and the grown garnet single crystal has a uniform thickness and a specular (mirror-like) surface without any crystal defects; and a magnetic garnet single crystal manufactured by the method. The magnetic garnet single crystal thus manufactured can be usefully applied to optical current transducers (CTs).

### BACKGROUND ART

In general, garnet single crystals are widely used for magneto-optical devices such as optical current transducers, optical isolators, optical switches and spatial optical modulators due to their excellent magneto-optical properties. Depending on ion species to be substituted and their sites, the magnetic, optical and magneto-optical properties of magnetic garnet single crystals are different, and a variety of wavelengths are used. Accordingly, various garnet single crystals having different compositions are used according to the kind of magneto-optical devices.

A typical garnet single crystal is manufactured by a liquid state epitaxial growth process (hereinafter, abbreviated as “LPE”). Specifically, a garnet single crystal is manufactured in accordance with the following procedure: after raw materials for a thick garnet single crystal film and a flux are melted at high temperature, the resulting melt is cooled to a temperature for crystal growth. Thereafter, a common Ca—Mg—Zr-substituted Gd₃Ga₅O₁₂ (SGGG) substrate is immersed in the cooled melt to grow a magnetic garnet single crystal film. The grown crystal film is taken out of the melt, and is then spun at 300˜500 rpm to remove the melt adhering to the surface of the crystal film (spin-off). Finally, the crystal film is etched to remove residual flux components present on the surface.

The flux is selected from B₂O₃—Bi₂O₃, PbO—B₂O₃ and Bi₂O₃-alkali metal oxide-based fluxes generally used for magnetic garnet single crystal raw materials.

Of these fluxes, B₂O₃—Bi₂O₃-based fluxes make the viscosity of a melt high and thus interfere with the migration of film-constituting materials present in the melt, causing non-uniform crystal growth. PbO—B₂O₃-based fluxes have a drawback that a small amount of highly volatile PbO contained in the fluxes is substituted into a crystal film, increasing the light absorption rate of the crystal film. Although Bi₂O₃— alkali metal oxide-based fluxes can solve the problem of B₂O₃—Bi₂O₃-based fluxes, i.e. non-uniform crystal growth due to a highly viscous melt, they are disadvantageous in terms of crystal growth time.

In order to solve the above-mentioned problems of the conventional fluxes, PbO—B₂O₃—Bi₂O₃-based fluxes have been developed and are currently used for growing garnet single crystals.

However, in the case that the PbO—B₂O₃—Bi₂O₃-based fluxes are used to grow garnet single crystals, crystal defects are apt to occur. These crystal defects require a high saturation magnetic field and a low coercive force. Accordingly, the PbO—B₂O₃—Bi₂O₃-based fluxes are not suitable for the manufacture of magnetic garnet single crystals for optical CTs requiring a low optical reflectivity and a high transmittance.

### DISCLOSURE OF THE INVENTION

The present inventors have earnestly and intensively conducted research to improve a method for growing a garnet single crystal using PbO—B₂O₃—Bi₂O₃ as a flux, and as a result, discovered an improved method for manufacturing a magnetic garnet single crystal for optical current transducers using a melt containing PbO—Bi₂O₃—B₂O₃ as a flux wherein the garnet single crystal is grown at a relative low temperature due to a reduced viscosity of the melt, and the grown garnet single crystal has a uniform thickness and specular surface without any crystal defects, thus accomplishing the present invention.

Therefore, it is an object of the present invention to provide a method for manufacturing a magnetic garnet single crystal using a melt containing garnet single crystal raw materials and Bi₂O₃—B₂O₃—PbO as a flux by liquid phase epitaxy (LPE) wherein the garnet single crystal is grown at a relative low temperature due to a reduced viscosity of the melt, and the grown garnet single crystal has a uniform thickness and a specular surface without any crystal defects.

It is another object of the present invention to provide a magnetic garnet single crystal manufactured by the method.

It is yet another object of the present invention to provide an optical device, such as an optical current transducer (CT), comprising the magnetic garnet single crystal.

In order to accomplish the above objects of the present invention, there is provided a method for manufacturing a magnetic garnet single crystal, comprising the steps of: adding 1˜3% by weight of an alkali metal oxide or carbide to a mixture of garnet single crystal raw materials and Bi₂O₃—B₂O₃—PbO as a flux, and melting the resulting mixture; and growing a garnet single crystal from the melt by liquid phase epitaxy.

According to the present invention, there is provided a magnetic garnet single crystal manufactured by the method wherein the magnetic garnet single crystal has a composition represented by the formula BiₐPb_{b}Y_{c}Gd_{3-(a+b+c)}Pt_{d}Fe_{5-d}O₁₂ (in which 0.5≦a≦1.0, 0≦b≦1.0, 0.3≦c≦1.0 and 0≦d≦1.0).

According to the present invention, there is provided an optical current transducer (CT) comprising the magnetic garnet single crystal.

### BEST MODE FOR CARRYING OUT THE INVENTION

The present invention will now be described in more detail.

According to the present invention, a garnet single crystal suitably applicable to optical current transducers (CTs) is manufactured in accordance with the following procedure: after 1˜3% by weight of an alkali metal oxide or carbide is added to a mixture of garnet single crystal raw materials and Bi₂O₃—B₂O₃—PbO as a flux, the resulting mixture is melted. Thereafter, a garnet single crystal is grown from the melt by a common liquid state epitaxial growth process. That is, the present invention is characterized by a melt containing an alkali metal oxide or carbide, garnet single crystal raw materials and Bi₂O₃—B₂O₃—PbO as a flux.

Since a melt containing garnet single crystal raw materials and a flux is highly viscous, some flux components may remain on a single crystal film after crystal growth on account of a high surface tension during spinning-off, which makes the formation of a specular surface difficult. Solutes present in the melt migrate to the surface of the film to grow a single crystal. However, the viscous melt interferes with the migration of the solutes, and thus causes the thickness of the film to be non-uniform.

The present inventors found that a less viscous melt facilitates the supply of film-constituting materials, and thus a thick magnetic single crystal film having a specular surface without any crystal defects is attainable. Based on this finding, the present inventors further added an alkali metal oxide or carbide to a melt commonly used for crystal growth.

When the alkali metal oxide or carbide is added in an amount of less than 1% by weight, based on the total weight of the melt, the viscosity of the melt is still high and thus crystal defects are likely to occur. Consequently, a magnetic garnet single crystal having a specular surface is not manufactured. When the alkali metal oxide or carbide is added in an amount exceeding 3% by weight, no crystal is grown or a garnet single crystal is not manufactured.

The alkali metal oxide or carbide is preferably selected from oxides and carbides of lithium, sodium, potassium and rubidium.

As described above, since the addition of the alkali metal oxide or carbide to a mixture of garnet single crystal raw materials and a flux can reduce the viscosity of the melt and can lower the crystal growth temperature, a magnetic garnet single crystal having a uniform thickness and a specular surface without any crystal defects can be manufactured.

In addition, the addition of the alkali metal oxide or carbide to a mixture of garnet single crystal raw materials and a flux in order to lower the crystal growth temperature, can increase the substitution amount of Bi³⁺ in a single crystal film, leading to a high magneto-optic coefficient. This is because the lowered crystal growth temperature increases the substitution amount of Bi³⁺. In other words, as the crystal growth temperature in the melt is lowered, the substitution of Bi³⁺ into the garnet single crystal film increases. Such crystal growth temperature can reduce manufacturing costs of garnet single crystals when manufactured on a commercial scale.

Furthermore, the addition of the alkali metal oxide or carbide to a mixture of garnet single crystal raw materials and a flux in order to reduce the viscosity of the melt, can be applied to all garnet single crystal raw materials for garnet single crystals applicable to optical devices.

In particular, garnet single crystal raw materials used in the present invention include those required for manufacturing a magnetic garnet single crystal having a composition represented by the formula BiₐPb_{b}Y_{c}Gd_{3-(a+b+c)}Pt_{d}Fe_{5-d}O₁₂ (in which 0.5≦a≦1.0, 0≦b≦1.0, 0.3≦c≦1.0 and 0≦d≦1.0).

In the composition, Bi³⁺ is substituted into a sublattice of the dodecahedral garnet crystal and acts to enhance the magneto-optical effects of the garnet crystal. As the substitution amount of Bi³⁺ increases, the magneto-optical effects increase linearly. However, this substitution of Bi³⁺ may negatively affect the temperature characteristics. For this reason, Gd³⁺ is added to improve the temperature characteristics. Pb and Pt are ion species substituted into the single crystal. Proper substitution amount of Pb and Pt assists in the improvement of magneto-optical or optical characteristics. When the substitution amount of Bi³⁺ is 0.5 or less, the magneto-optical performance is deteriorated. When the substitution amount of Bi³⁺ exceeds 1.0 or more, the temperature characteristics are worsened and even the garnet phase may not be crystallized.

A mixture of the garnet single crystal raw materials, Bi₂O₃—B₂O₃—PbO as a flux and the alkali metal oxide or carbide is melted, and then a crystal is grown from the melt by liquid state epitaxy to manufacture a high-quality garnet single crystal.

The mixture can be heated to 1200° C. or higher to melt it using a common LPE apparatus. The single crystal growth is performed in a Class 500 clean room due to the sensitivity to foreign matters. As a substrate, Ca—Mg—Zr-substituted Gd₃Ga₅O₁₂ (SGGG) is commonly used.

The LPE process will now be explained briefly. First, garnet single crystal raw materials, a flux, and an alkali metal oxide or carbide are mixed and ground. After the ground mixture is charged into a platinum crucible, the crucible is placed in an LPE furnace to melt the mixture therein. After melting, the melt is cooled to a temperature for magnetic garnet film growth. An SGGG substrate washed with the melt descends to a point close to the level of the melt, and is maintained so as to reach the thermal equilibrium state between the substrate and the melt. Thereafter, the substrate is immersed in the melt so that a crystal is grown. At this time, the substrate is rotated at 75 rpm while turning the other side at an interval of 2 seconds. This is carried out to provide the same growth atmospheres to the overall surface of the substrate and to uniformly maintain the growth speed of a film. After completion of growth, the grown magnetic garnet single crystal is taken out of the melt. Next, the magnetic garnet single crystal is spun at 300˜500 rpm to remove some melt components adhering to the surface of the film (spin-off). Finally, residual flux components present on the surface of the grown single crystal film are etched to manufacture a final garnet single crystal.

The garnet single crystal manufactured by an LPE process, particularly, the garnet single crystal manufactured from the melt containing the garnet single crystal raw materials, the flux and the alkali metal oxide or carbide in accordance with the method of the present invention has a uniform thickness and a specular surface without any crystal defects. Accordingly, the magnetic garnet single crystal thus manufactured can be usefully applied to optical current transducers (CTs).

The present invention will now be described in more detail with reference to the following examples. However, these examples are given for the purpose of illustration and are not to be construed as limiting the scope of the invention.

### EXAMPLE 1

67.286 g of Bi₂O₃, 72.035 g of PbO, 3.5 g of B₂O₃, 0.556 g of Y₂O₃, 0.516 g of Gd₂O₃, 6.107 g of Fe₂O₃ and 1.9757 g of Na₂CO₃ were charged into a platinum crucible, and then melted at 1,000° C. Then, the melt was cooled to 790° C. A garnet single crystal was manufactured from the melt using an SGGG substrate by a common LPE process.

### EXAMPLE 2

A single crystal was manufactured in the same manner as in Example 1, except that 4.0004 g of Na₂CO₃ was added.

### COMPARATIVE EXAMPLE 1

A single crystal was manufactured in the same manner as in Example 1, except that Na₂CO₃ was not added.

### COMPARATIVE EXAMPLE 2

A single crystal was manufactured in the same manner as in Example 1, except that Na₂CO₃ was not added and the melt was cooled to 820° C.

### COMPARATIVE EXAMPLE 3

A single crystal was manufactured in the same manner as in Example 1, except that 1.9757 g of Na₂CO₃ was not added and the melt was cooled to 820° C.

### COMPARATIVE EXAMPLE 4

A single crystal was manufactured in the same manner as in Example 1, except that 6.0000 g of Na₂CO₃ was added.

### EXPERIMENTAL EXAMPLE 1

Defects of the garnet single crystals manufactured in Examples 1 and 2, and Comparative Examples 1 to 4 were counted. In addition, the thickness of residual flux after spinning-off was measured, and the thickness deviation values were calculated. The results are shown in Table 1 below.

TABLE 1

| | | | Crystal | | Number of | Thickness of | Thickness |
|---|---|---|---|---|---|---|---|
| | | Amount of | growth Temp. | Thickness | defects | residual | deviation |
| Exam. No. | Composition | Na₂CO₃ (g) | (° C.) | (μm) | (1 cm × 1 cm) | flux (μm) | (μm) |
| Exam. 1 | Bi_{0.85}Pb_{0.02}Y_{0.60}Gd_{1.53}Pt_{0.02}Fe_{4.98}O₁₂ | 1.9757 | 790 | 100 | 0˜1 | 20 | ±1 |
| Exam. 2 | Bi_{0.82}Pb_{0.02}Y_{0.66}Gd_{1.56}Pt_{0.02}Fe_{4.98}O₁₂ | 4.0004 | 790 | 70 | 0˜1 | 20 | ±1 |
| Comp. Exam. 1 | Bi_{0.90}Pb_{0.02}Y_{0.51}Gd_{1.57}Pt_{0.02}Fe_{4.98}O₁₂ | 0 | 790 | 130 | 20˜30 | 100 | ±5 |
| Comp. Exam. 2 | Bi_{0.58}Pb_{0.02}Y_{1.00}Gd_{1.40}Pt_{0.02}Fe_{4.98}O₁₂ | 0 | 820 | 100 | 8˜12 | 50 | ±2 |
| Comp. Exam. 3 | Bi_{0.61}Pb_{0.02}Y_{1.10}Gd_{1.27}Pt_{0.02}Fe_{4.98}O₁₂ | 1.9757 | 820 | 60 | 2˜3 | 15 | ±1 |
| Comp. Exam. 4 | Not grown | 6.0000 | 790 | 0 | — | 15 | 0 |

As can be seen from Table 1, the addition of Na₂CO₃ lowered the crystal growth temperature. In particular, as the amount of Na₂CO₃ added increased, the thickness of the residual fluxes increased. This result is based on increased viscosity of the melts. It was also confirmed from Table 1 that the larger the thickness of the residual fluxes, the greater the number of defects, and conversely the smaller the thickness of the residual fluxes, the lower the number of defects. Furthermore, the lower the viscosity of the melts, i.e. the smaller the thickness of the residual fluxes, the more uniform the thickness of the fluxes.

In conclusion, since a less viscous melt facilitates the supply of crystal-constituting materials, a garnet single crystal having a uniform thickness can be manufactured. Moreover, since the decrease in the thickness of residual flux after spinning-off can reduce the reaction with the crystal surface during cooling, a garnet single crystal having a uniform thickness and a specular surface can be manufactured.

### INDUSTRIAL APPLICABILITY

As apparent from the above description, according to the method of the present invention, a garnet single crystal having a uniform thickness and a specular surface without any crystal defects can be manufactured from a melt containing garnet single crystal raw materials, Bi₂O₃—B₂O₃—PbO as a flux and an alkali metal oxide or carbide by liquid phase epitaxy (LPE). At this time, the garnet single crystal is grown at a relatively low temperature due to a reduced viscosity of the melt. The magnetic garnet single crystal thus manufactured can be usefully applied to optical devices, e.g., optical current transducers (CTs).

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method for manufacturing a magnetic garnet single crystal, comprising the steps of:
adding 1˜3% by weight of an alkali metal oxide or carbide to a mixture of garnet single crystal raw materials and Bi₂O₃—B₂O₃—PbO as a flux, and melting the resulting mixture; and
growing a garnet single crystal from the melt by liquid phase epitaxy.

2. The method according to claim 1, wherein the alkali metal oxide or carbide is selected from oxides and carbides of lithium, sodium, potassium and rubidium.

3. The method according to claim 1, wherein the magnetic garnet single crystal has a composition represented by the formula BiₐPb_{b}Y_{c}Gd_{3-(a+b+c)}Pt_{d}Fe_{5-d}O₁₂ (in which 0.5≦a≦1.0, 0≦b≦1.0, 0.3≦c≦1.0 and 0≦d≦1.0).

4. A magnetic garnet single crystal having a composition represented by the formula BiₐPb_{b}Y_{c}Gd_{3-(a+b+c)}Pt_{d}Fe_{5-d}O₁₂ (in which 0.5≦a≦1.0, 0≦b≦1.0, 0.3≦c≦1.0 and 0≦d≦1.0), manufactured by the method according to claim 1.

5. An optical current transducer (CT) comprising the magnetic garnet single crystal according to claim 4.
